(19) United States
(12) Patent Application Publication
(10) Pub. No.: US 2015/0295157 A1
(43) Pub. Date: Oct. 15, 2015

(54) THERMOELECTRIC CONVERTER

(71) Applicants: Airbus Operations (S.A.S.), Toulouse Cedex (FR); Airbus (S.A.S.)

(72) Inventors: Philippe Tatry, Balma (FR); Sébastien Berhouet, La Salvetat St Gilles (FR)

(21) Appl. No.: 14/694,638

(22) Filed: Apr. 23, 2015

Related U.S. Application Data
(63) Continuation of application No. PCT/FR2013/052538, filed on Oct. 23, 2013.

(30) Foreign Application Priority Data
Oct. 23, 2012 (FR) 1260095
Apr. 3, 2013 (FR) 1352991

(51) Int. Cl. H01L 35/30

(52) U.S. Cl. CPC H01L 35/30

(57) ABSTRACT

An energy conversion system comprising: a conversion unit for converting thermal energy into electrical energy, said unit comprising at least one thermal exchange surface for exchanging thermal energy with at least one external heat source, and a thermal inertia unit configured to cooperate with the conversion unit to slow down the return of the conversion unit to thermal equilibrium during the exchange of thermal energy.

### CROSS-REFERENCE TO RELATED APPLICATIONS

This application claims priority to PCT Application No. PCT/FR2013/052538 filed Oct. 23, 2013, which claims priority to French Application Nos. 1260095 filed Oct. 23, 2012 and 1352991 filed Apr. 3, 2013, the entire disclosures of which are incorporated by reference herein.

### TECHNICAL FIELD

The present disclosure relates to an energy converter for producing electrical energy. It relates also to the use of such a converter in an aircraft.

### BACKGROUND

Modern aircraft have a large number of electrical devices embedded therein. These devices are used for the piloting and the instrumentation of the aircraft and/or also have other uses for the crew or the passengers.

The embedded devices can be of widely varying kinds. These devices are, for example, sensors.

Sensors are used for the onboard monitoring of a very large number of parameters (temperature, pressure, mechanical stresses or other). The number of these parameters, whether it is a test aircraft or a commercial aircraft, can run to several thousand. These sensors are further positioned in numerous areas of the aircraft (engine areas, struts, cargo hold, cabin, cockpit, landing gear and closures, wings, moving surfaces, rear cone, or other).

These areas can be difficult to access and can pose problems in installing the sensors.

In particular, the sensors have to be electrically powered. Typically, the sensors are powered electrically by dedicated wiring or by a standalone electrical source based on dry cells or batteries installed close to the sensors.

These two electrical power supply modes induce constraints for the design of the aircraft, notably in terms of production, installation and maintenance.

For example, the powering of the sensors by dedicated wiring has impacts, notably on:
the weight of the aircraft: the weight of the wiring, of the bundle supports, of the local structural reinforcements, or other, increase the weight of the aircraft, which consequently increases the fuel consumption of the aircraft.
The installation of the sensors: this can prove very complex in terms of design, production, maintenance (problems of accessibility of the wiring, of the ability to withstand heat, vibrations, or other).

Also by way of example, the powering of the sensors by electrical energy storage sources (dry cells, batteries, or similar) installed locally has impacts, notably on:
the design of these storage sources: they have to retain their storage capacity in the severe environmental conditions of the aircraft (cold/hot thermal cycles, vibrations, or similar);
the maintenance operations: since the life span of these storage sources is limited in time, accessibility to these sources has to be provided although the associated sensors are sometimes installed in areas with very little access, for measurement needs.

The constraints discussed above are imposed on aircraft dedicated to the commercial airlines and also on aircraft dedicated to in-flight testing.

For the latter type of aircraft, there is an additional objective of quick and easy installation of the sensor-wiring assemblies in various places depending on the test to be carried out.

The issues of installing electrical devices and their power supplies have been illustrated with reference to sensors. However, these issues can also exist for other types of electrical devices. These issues can moreover be encountered in other environments other than that of an aircraft.

Thus, there is a need to improve the electrical power supply of the electrical devices, notably of the devices embedded in the aircraft.

### SUMMARY

The present disclosure falls within this context.

A first aspect of the disclosure herein relates to an energy conversion system comprising:
a conversion unit for converting thermal energy into electrical energy, the unit comprising at least one thermal exchange surface for exchanging thermal energy with at least one external thermal source, and
a thermal inertia unit configured to cooperate with the conversion unit to slow down the return of the conversion unit to a thermal balance upon the exchange of thermal energy.

A system according to the first aspect makes it possible to produce a stand alone power source and makes it possible to replace the current solutions that require power supply wiring and/or batteries.

A system according to the first aspect can make it possible to power the sensors, for example in an aircraft.

Thus, the efficiency of the aircraft can be enhanced through a weight saving offered by the elimination of the wiring and/or of the batteries.

Furthermore, a system according to the first aspect is easy to install because there is no need to design the installation of the wiring and its fastenings to the structures, equipment items, or anything else.

A system according to the first aspect takes advantage of thermal energy sources present within the very aircraft.

The conversion unit makes it possible to generate the electrical energy and thermal inertia unit makes it possible to maintain a more long-term temperature gradient to generate this electrical energy more sustainably.

A system according to the first aspect therefore performs an optimal energy conversion.

The maintenance of the systems according to the first aspect is more simple because they do not require complex electrical power supply wiring.

The systems according to the first aspect exploit thermal sources that are not generally exploited to generate the energy powering the electrical devices.

Thermal exchange between the conversion unit and the external thermal source can be done by direct or indirect thermal contact. In the case of indirect thermal contact, an element can be inserted between thermal exchange surface of the conversion unit and thermal exchange surface of the external thermal source. For example, the inserted element comprises a thermal inertia unit. In the case of a direct thermal contact, thermal exchange surface of the conversion unit and thermal exchange surface of the external thermal source are directly in thermal contact (a thermal paste can, however, be used to promote this thermal contact).

According to embodiments, thermal inertia unit comprises a phase-change material.

These materials offer a good thermal inertia and make it possible to maintain a temperature difference for the generation of energy by the conversion unit.

For example, the conversion unit comprises a semiconductor-based circuit.

Thus, this unit can be of smaller dimensions.

This unit can, for example, operate according to the Seebeck effect.

According to embodiments, the surface is insulated by a protection jacket, the at least one thermal exchange surface remaining free for thermal exchange.

Thus, it is possible to protect thermal inertia unit from impacts that can cause, for example, the phase-change material to escape. The phase-change material is thus contained.

For example, the system further comprises a storage unit for storing, at least partly, the converted electrical energy.

Thus, the energy generated can be used even when the temperature difference has disappeared within the conversion unit, after a return to thermal equilibrium.

Also for example, the system further comprises at least one first thermal connection element in thermal contact with a first thermal exchange surface of the conversion unit, the first element being configured to guide a heat transfer between a first external thermal source and the first thermal exchange surface.

Thus, it is possible to reach thermal sources that are far away from the system or with little access.

For example, the system further comprises at least one second thermal connection element in thermal contact with a second thermal exchange surface of the conversion unit, the second element being configured to guide a heat transfer between a second external thermal source and the second thermal exchange surface.

Thus, it is possible to place the conversion unit in thermal contact with two thermal sources that are far apart and that have very different temperatures. This makes it possible to maximize the temperature difference and therefore the electrical energy generated.

According to embodiments, the at least one exchange surface is at least partly covered with an interface layer for thermal conduction with the at least one thermal source.

Thus, thermal contact is optimized.

For example, the interface layer comprises a sublayer of double-sided adhesive tape.

Thus, the fixing is also optimized.

For example, the double-sided adhesive tape is positioned around a sublayer of thermal conduction material.

The sublayer of thermal conduction material can comprise GAP PAD 3000S.

The sublayers of double-sided adhesive tape and of thermal conduction material have, for example, one and the same thickness.

For example, the sublayers of double-sided adhesive tape and of thermal conduction material are incorporated in one and the same independent interface element. This element is, for example, a patch or a strip cut from a roll.

A second aspect of the disclosure herein relates to an aircraft comprising a system according to the first aspect.

For example, the at least one thermal source is chosen from the structural elements of the aircraft.

Also for example, the system supplies at least one sensor with electrical energy.

A third aspect of the disclosure herein relates to a method for supplying electrical power to an electrical device in an aircraft, comprising the following steps of:
selection of at least one thermal source in the aircraft,
thermal contact of at least one exchange surface of a conversion unit of a system according to the first aspect with the at least one selected thermal source, and
connection of the system to the electrical device.
For example, the at least one thermal source is selected from the structural elements of the aircraft.

Also for example, the at least one thermal source is chosen in such a way as to optimize a temperature difference within the conversion unit of the system.

The objects according to the second and third aspects of the disclosure herein secure at least the same benefits as those secured by the system according to the first aspect.

### BRIEF DESCRIPTION OF THE DRAWINGS

Other features and advantages of the disclosure herein will become apparent on reading the following detailed description, given as a nonlimiting example, and the attached figures in which:

FIG. 1 schematically illustrates a system according to embodiments;

FIG. 2 illustrates an exemplary installation of a system according to embodiments;

FIG. 3 illustrates areas of installation in an aircraft for a system according to embodiments;

FIGS. 4, 5a and 5b illustrate embodiments of the energy conversion systems;

FIG. 6 schematically illustrates the general principle of operation of a thermoelectric conversion unit according to embodiments;

FIGS. 7, 8a and 8b illustrate thermoelectric conversion units according to embodiments;

FIG. 9 is a flow diagram of steps of methods according to embodiments; and

FIGS. 10a-10d illustrate a mounting interface according to embodiments.

### DETAILED DESCRIPTION

Hereinbelow, a conversion system is described that makes it possible to transform the available thermal energy (usually lost in the form of heat and not used) in a vehicle, such as an aircraft, into electricity. The disclosure herein is not however limited to a use in a vehicle or an aircraft.

The system comprises an energy conversion unit such as, for example, one or more thermoelectric generators. This conversion unit is coupled to a thermal inertia unit comprising, for example, a phase-change material.

The duly generated electrical energy is, for example, used to power sensors. The disclosure herein can, however, be used to power other types of electrical devices.

A system as described hereinbelow can, for example, be installed in place of or in addition to conventional electrical energy generation sources.

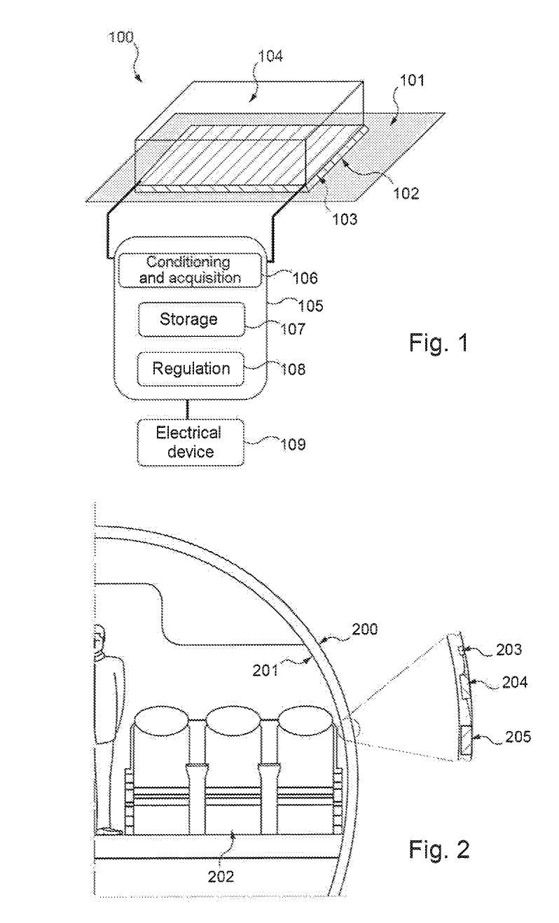

FIG. 1 schematically illustrates a system according to embodiments.

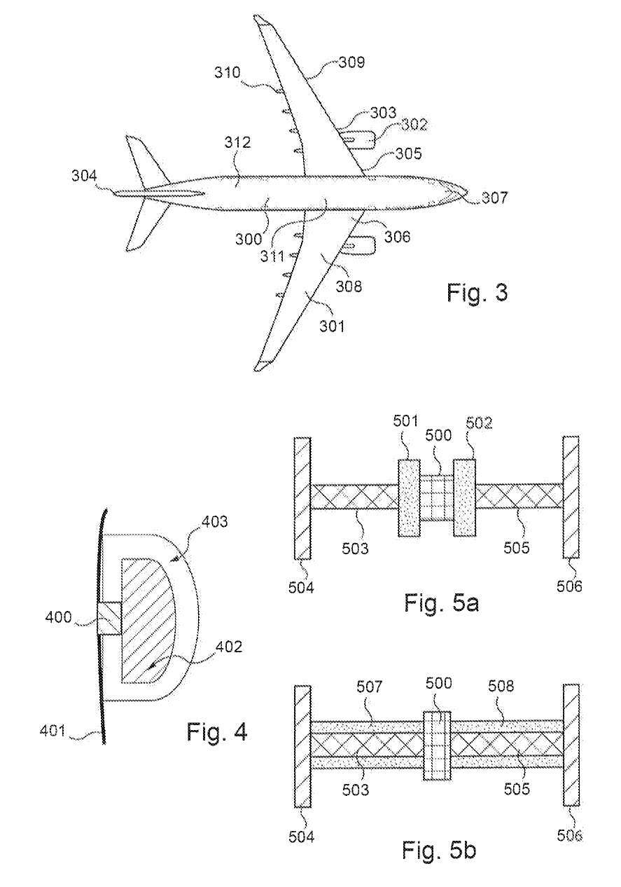

The system 100 is positioned on a thermal source 101 (which can be hot or cold). For example, this thermal source is a surface of an element of an aircraft. Examples of such elements are given with reference to FIG. 3.

To interface the system with the heat source, the system comprises an interface layer 102. This interface layer makes it possible to ensure a good transfer of thermal flux between the system and thermal source. It is, for example, a glue or a thermal paste charged with thermally-conductive particles and exhibiting a low thermal resistance. Such an interface allows for a simple and rapid installation without damaging thermal source.

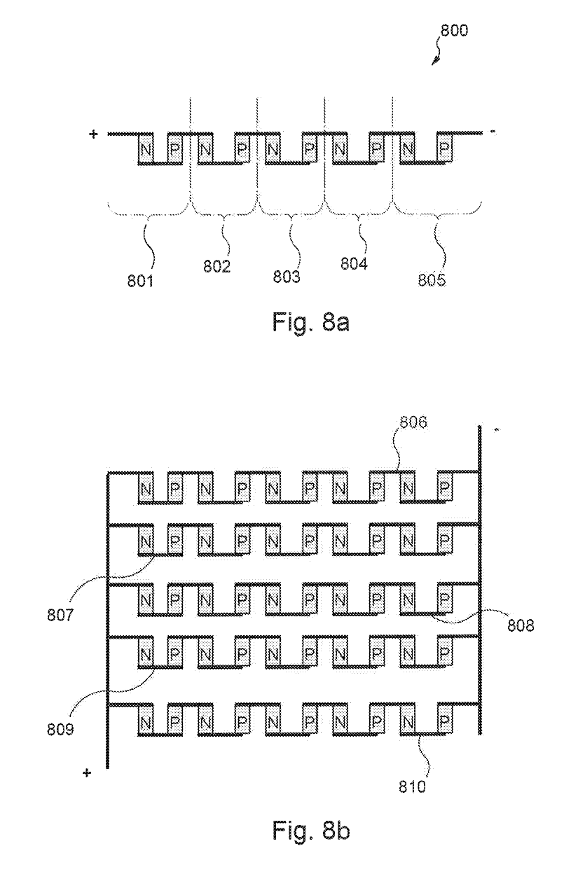

The interface layer is in thermal contact with the heat source on the one hand, and a thermal exchange surface of the system on the other hand. This exchange surface is that of an energy conversion unit 103 configured to convert thermal energy into electrical energy. For example, this unit includes an array of thermoelectric generators as is described with reference to FIGS. 7, 8a and 8b.

A thermal inertia unit 104 is positioned in thermal contact with the conversion unit 103. For example, the unit 104 comprises a vessel containing a phase-change material.

Phase-change materials are materials whose phase-change properties (gas/liquid/solid) as a function of the temperature to which they are subjected are exploited. These phase changes are sublimation (transition from the solid state to the gaseous state), melting (transition from the solid state to the liquid state) and vaporization (transition from the liquid state to the gaseous state).

The phase change is accompanied by absorption (or rejection) of the enthalpy difference between the two final and initial phases. Thus, the phase-change materials have a thermal inertia which makes it possible to slow down heating or cooling.

Phase-change materials that can be used are, for example, water, metals/alloys (gallium, eutectic Bi—Pb—Sn—Cd or similar), hydrated salts, organic materials (polyethylene glycol or similar), paraffins.

Paraffins are made up of linear molecules of straight-chain saturated hydrocarbons whose chemical formula is of the type CₙH₂ₙ₊₂. Depending on the length of the molecule, the paraffins can be in the solid state when n lies approximately between 20 and 40 (the paraffin then takes the form of paraffin wax, in the liquid state when n lies approximately between 8 and 19).

The melting point (Tf) of the paraffin waxes lies generally between 45° C. and 70° C. approximately depending on the chemical composition. However, some go beyond, such as, for example, the paraffin wax of “microcrystalline” type which contains compounds with high molecular weight (hydrocarbons with iso-paraffinic branches and naphthenic hydrocarbons) has a melting point of the order of 90° C. The specific heat (Cp) of the paraffin waxes is of the order of 2100-2900 J.kg⁻¹.K⁻¹ and their enthalpy of fusion (ΔHf) is of the order of 200-220 kJ.kg⁻¹.

The paraffin waxes (C₂₅H₅₂) thus constitute suitable materials for producing thermal inertia units (for example for storing heat).

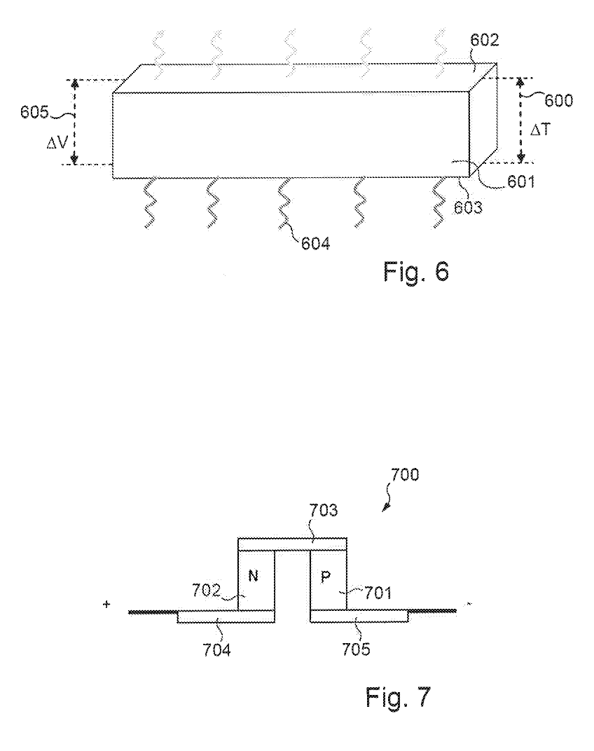

Thus, more generally, the conversion unit makes it possible to generate an electrical potential difference, from a temperature difference between its exchange surface with thermal source and its surface in thermal contact with the unit 104. Thermal inertia unit 104 makes it possible to delay the return of the conversion unit to thermal balance between its exchange surfaces with thermal source and the unit 104. Thus, the temperature difference is maintained for a longer time, which makes it possible to generate the potential difference for a longer time and thus to generate a greater quantity of electrical energy. The principle of this energy conversion is described in more detail with reference to FIG. 6.

The conversion unit 103 is connected to a module 105 for managing the electrical energy generated. This module is configured to adapt the electrical energy generated to the use which has to be made thereof.

The management module 105 comprises an acquisition and conditioning unit 106.

This unit makes it possible, for example, to perform an impedance matching. In effect, the output impedance of the conversion unit 103 has to be matched in impedance in order for the current/voltage bearing to be compatible with the load to be powered with the best possible efficiency.

The unit 106 can further comprise a “boost” circuit (or parallel chopper) to raise the voltage at the output of the unit 103.

The management module 105 can further comprise an electrical energy storage unit 107, for example in order to offer a reserve of buffer energy to cope with any fluctuations of thermal energy available at the source. For example, the available thermal energy can change according to the flight phase of the aircraft. The storage unit 107 comprises, for example, supercapacitors or thin-film batteries.

The management module 105 can also comprise a regulation unit 108 in order to adapt the voltage levels delivered to the powered electrical device 109 (for example a sensor).

In order to reduce the losses introduced by the components of the management module, these components can be chosen from the family of low power consumption components. Furthermore, in order to reduce the dimensions of the management module, these components can be arranged in one and the same circuit.

An exemplary installation of a system as described previously is presented with reference to FIG. 2.

FIG. 2 represents a partial view in cross section of an aircraft. It shows a part of the fuselage 200 of the aircraft, the corresponding part of the internal cladding 201, and a row of seats 202.

It is assumed that there is a sensor 203 on the fuselage of the aircraft. For example, it is a strain gauge for measuring the deformations of the fuselage in flight. The sensor 203 is powered via a management module 204 (as described previously) by an energy conversion system 205.

As can be seen, the bulk due to the sensor and to its power supply is reduced. It does not require a stand alone battery or complex wiring. Moreover, this installation is totally independent and does not require any particular connection to power supply cables running through the aircraft.

An energy conversion system as described can be installed in various other areas of the aircraft. Such areas are presented with reference to FIG. 3.

The areas of the aircraft that can advantageously be used are those in which there is a significant temperature difference. This makes it possible to optimize the electrical energy generated by the conversion unit (for example by maximizing the Seebeck effect as described with reference to FIG. 6).

The areas used are, for example, the cold areas such as the external structures of the fuselage 300, wings 301, moving surfaces, or similar. The frames, the stringers, the stiffeners, and other such elements can be cited.

The areas used are also, for example, the hot areas such as the engine areas 302, the strut area 303 at the interface of the aerofoil with the engine. For example, in the area of the pre-coolers, temperatures of approximately 150° C. are observed. The other areas that can be cited include the area 304 of the auxiliary power engine, called APU (Auxiliary Power Unit), the area of the air conditioning machine 305 (so-called “pack” area) which is located in an unpressurized area (although ventilated, the temperature of this area can range up to 70-80° C.), the pressurized hot air intakes on the engines 306 (the so-called “bleed” lines), the internal temperature of which is of the order of 200° C., even occasionally 260° C., the air inlet areas equipped with heating de-icing systems, the electrical master boxes 307 (which heat by Joule effect) which allow the electrical distribution in the aircraft, the electrical current and voltage converters, the brakes 308 on the landing gears (temperatures up to 400° C. can be observed, notably in cases of RTO, an acronym standing for “Rejected Take-Off”), the leading edges of the wings 309 in which are installed electrical runs which can heat up by Joule effect and bleed pipes containing very hot air (these areas can reach up to 90° C.). Other areas that can be cited include the local area 310 of the electro-hydraulic actuators in the aerofoils that can exhibit a temperature up to approximately 110° C. in the absence of ventilation, the areas 311 containing the controllers of different systems (such as hydraulic pumps, thermal machines, or other such devices), the box housing area of certain flap tracks (the heat exchanger for the hydraulics which can be located in this area, the temperature can reach up to 80° C. in certain hydraulic pressure variation conditions), the area 312 above the baggage hold in the cabin (area called “crown”) in which the socket caps of the lamps are installed (heating by Joule effect) and which are additionally insulated with a thermo-acoustic insulation to ensure the comfort of the passengers (in hot weather, the temperature can reach up to 60° C.). The fuel cells (PEMFC, SOFC, or other such) or even other areas can also be cited.

An embodiment of a conversion system is described with reference to FIG. 4.

A conversion unit 400 is arranged against a wall 401 of the aircraft. The unit 400 is thus in thermal contact by its exchange surface with thermal source here consisting of the wall 401. A thermal inertia unit 402 is arranged against the conversion unit in thermal contact therewith. Thus, a temperature difference is maintained for a fairly long time to generate electrical energy. In order to protect the system, a protection jacket 403 encloses the conversion unit and thermal inertia unit.

The system powers an electrical device (not represented) via a generated electrical energy management module (not represented).

Another embodiment of a conversion system is described with reference to FIG. 5a.

The unit for converting thermal energy into electrical energy 500 is thermally connected to two thermal inertia units 501 and 502 by two different thermal exchange surfaces. A thermal connection element 503, for example a conductor bar, links the unit 501 to a wall 504 constituting a first thermal source. Another thermal connection element 505 links the unit 502 to another wall 506 constituting a second thermal source.

The use of the connection elements makes it possible to link two thermal sources that are remote from one another but whose respective temperatures offer a significant temperature gradient, thus allowing for a greater generation of electrical energy by the conversion unit 500.

The system of FIG. 5a comprises two connection elements. However, it is possible to provide only one thereof. Furthermore, even in the case where two connection elements are used, there is not necessarily any recourse to two thermal inertia units. It is possible to envisage that a connection element is associated with one thermal inertia unit and not the other.

A variant of the preceding embodiment is described with reference to FIG. 5b.

This figure once again contains the elements common to the system of FIG. 5a. The elements 500, 503, 504, 505 and 506 are thus identical to those of FIG. 5a.

In the variant of FIG. 5b, thermal inertia units 507 and 508 are simultaneously in thermal contact with the conversion unit 500, the sources and the connection elements. Thus, for example, thermal inertia unit 508 encloses the connection element 505 and is also in thermal contact with the unit 500 on the one hand and the source 506 on the other hand. For its part, thermal inertia unit 507 encloses the connection element 503 and is also in thermal contact with the unit 500 on the one hand and the source 504 on the other hand.

As for the system of FIG. 5a, the system of FIG. 5b comprises two connection elements, but it is possible to provide only one thereof. Furthermore, even in the case where two connection elements are used, there is not necessarily any recourse made to two thermal inertia units. It is possible to envisage that a connection element is associated with one thermal inertia unit and not the other.

Thermoelectric conversion units according to embodiments are described hereinbelow.

Such units can, for example, rely on the “Seebeck” effect. According to this effect, electricity can be produced from a temperature difference applied to an element in a sensitive material.

When a temperature difference is applied to the element, this results in a variation of the Fermi energy through the material thus creating a potential difference which generates an electrical current by diffusion of the electrical charges. Thermal conductivity in the material is obtained via the phonons.

The general principle of operation of a thermoelectric conversion unit (or thermoelectric generator) can be schematically represented according to FIG. 6.

A temperature difference AT represented by the double arrow 600 is applied to a parallelepipedal bar 601 between two faces 602 and 603. It is assumed that the face 602 is the “cold” face and that the face 603 is the “hot” face. These faces are called “cold” and “hot” in as much as the temperature applied to the face 602 (cold) is lower than that applied to the face 603 (hot). Thus, a thermal flux, represented by arrows 604 passes through the bar. By Seebeck effect, a potential difference ΔV is created between the faces 602 and 603 represented by the double arrow 605.

The potential difference can be expressed as ΔV=S. ΔT, S being the Seebeck coefficient of the material from which the bar 601 is formed.

The power (P) of thermoelectric generator thus formed by the bar to which the temperature difference is applied can then be expressed:

P=(2.S. ΔV)²/(4.RTEG), RTEG being thermal resistance of the bar.

Thermal resistance can be expressed RTEG=2.n.p.(L₀/A₀), in which n is the number of elements forming the generator (here n=1), p is the electrical resistivity of the element, L₀ is the length of the element and A₀ is the cross-sectional area of the element.

A practical embodiment of a thermoelectric generator is illustrated by FIG. 7.

Thermoelectric generator 700 of FIG. 7 relies on the following principle. A positively doped (P) semiconductor element 701 and another, negatively doped (N) semiconductor element 702 are placed between a hot source and a cold source (not represented). The semiconductor elements are, for example, based on bismuth-tellurium (Bi₂Te₃) and placed on ceramic plates (other materials are possible, notably: SiGe, TAGS, FeSi₂, Zn₄Sb₃, CeFe₃CoSb₁₂, Ba₈GaₓGe₄₆₋ₓ, NaCO₂O₄, Bi₂Te₃Sb₂Te₃, SiSiGe, B₄CB₃C).

The sources are called “hot” and “cold” in as much as the temperature of the hot source is higher than the cold source. The cold source is in thermal contact with the faces 704 and 705 of the generator connecting the semiconductor elements respectively 702 and 701. The hot source is in thermal contact with the face 703 connected to the semiconductor elements 701 and 702.

By the Seebeck effect, a current is created by thermal diffusion of the electrons and of the “holes”. Thus, the face 704 constitutes the positive terminal of the generator and the face 705 the negative terminal.

Thermoelectric generators can be electrically connected in series and thermally connected in parallel. This assembly 800 is represented in FIG. 8a. It comprises five generators 801, 802, 803, 804 and 805. It could comprise another number thereof. The generators of the assembly 800 have the same structure as that described with reference to FIG. 7.

Thus, the negative terminal of the generator 801 (the one connected to the P-doped semiconductor element) is connected to the positive terminal of the generator 802 (the one connected to the N-doped semiconductor element). The negative terminal of the generator 802 is connected to the positive terminal of the generator 803. The negative terminal of the generator 803 is connected to the positive terminal of the generator 804. The negative terminal of the generator 804 is connected to the positive terminal of the generator 805.

The positive terminal of the generator 801 thus forms the positive terminal of the assembly and the negative terminal of the generator 805 forms the negative terminal of the assembly.

The positive and negative terminals of each generator are in thermal contact with the same hot source. In each generator, the face linking the N-doped and P-doped semiconductor elements is in thermal contact with the same cold source.

To connect the generators in series electrically as described above, a silver glue can, for example, be used.

Other assemblies are possible. For example, as illustrated by FIG. 8b, it is possible to associate subassemblies as described with reference to FIG. 8a in parallel.

The assembly of FIG. 8b comprises five subassemblies 806, 807, 808, 809 and 810 having the structure described with reference to FIG. 8a. Another number of subassemblies is possible.

The positive terminals of the subassemblies are connected together. The negative terminals of the subassemblies are connected together. For example, the terminals of all thermoelectric generators forming the subassemblies are in thermal contact with the same hot source. The faces linking two N-doped and P-doped semiconductor elements of thermoelectric generators forming the subassemblies can, for example, be in thermal contact with the same cold source.

When installing energy conversion systems according to the embodiments, the selected architecture can be either centralized (with one conversion system powering several electrical devices) or decentralized (with one conversion system powering each electrical device). This choice can be made notably as a function of the constraints of required power, weight, available volume, failure propagation, segregation of the systems to observe safety requirements, reliability, availability, or other such factors.

It is also possible to choose the appropriate architecture as a function of the needs of each electrical device to be powered.

A thermoelectric conversion unit comprising an assembly of generators as described above can measure a few square millimeters.

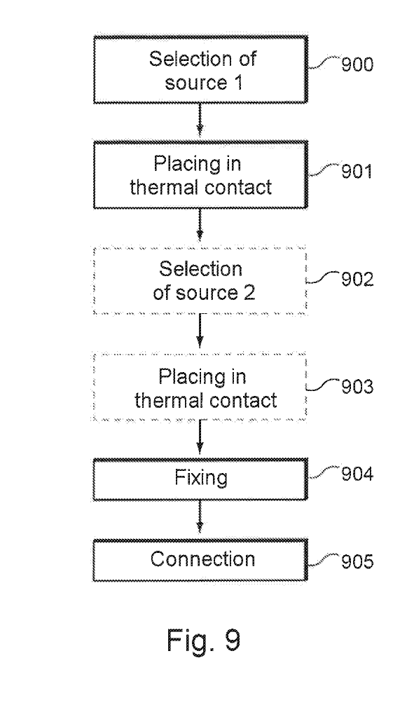

The installation of a system according to embodiments for powering an electrical device in an aircraft can be done in accordance with the method described with reference to the flow diagram of FIG. 9.

In a first step 900, a thermal source is selected in order to create a temperature gradient in the energy conversion system. This thermal source can be a structural element of the aircraft. It can be chosen from those described with reference to FIG. 3. For example, this thermal source is a source with high temperature (engine area or similar) or a source with low temperature (cladding of the aircraft or similar).

In a step 901, the selected thermal source is placed in thermal contact with an exchange surface of the energy conversion unit. For example, this source is placed in contact with faces of a set of thermoelectric generators as described previously. This placement in contact can, for example, be done via a thermal connection element as described with reference to FIGS. 5a and 5b or by using a thermal paste to improve thermal contact.

A system using a single thermal source, such as that described with reference to FIG. 4, can be used. The electrical energy is then generated by the temperature difference between that of thermal source and the ambient temperature in which the system is immersed.

Optionally, another thermal source can be selected in a step 902. This entails, for example, selecting a thermal source whose temperature is very different from the temperature of the source selected in the step 900. It is thus possible to optimize the temperature difference within the conversion unit of the system. The choice of a second thermal source can be made as a function of the location in the aircraft and of the device to be powered. A great temperature difference can make it possible to generate a greater quantity of energy. It is thus possible to power an electrical device of greater consumption.

In a step 903, the second thermal source selected in the step 902 is connected to another exchange surface of the conversion unit.

In a step 904, the system is fixed, for example by a glue or a temporary fixing element. Alternatively, the system can simply be positioned in a casing in proximity to the device to be powered.

The system is then electrically connected to the electrical device to be powered in a step 905.

A system according to embodiments can be mounted on the internal wall of an aircraft fuselage. A number of constraints can then be taken into account.

The mounting (and the removal) of the system needs to be rapid. Thus, a simple mounting (and removal) principle is preferable, particularly in the context of installation of the system for easy instrumentation of a test aircraft in flight for very short testing campaigns.

The mounting (and the removal) of the system needs to be reliable. In particular, the mounting principle needs to be compatible with the vibratory surroundings of an aircraft. It is in effect advisable to avoid having the system become detached from the wall.

Furthermore, the mounting principle of the system must not damage the wall on which it is mounted.

Alongside these mounting constraints, as explained above in the description, thermal resistance must be minimized to optimize the power available at the output of the system.

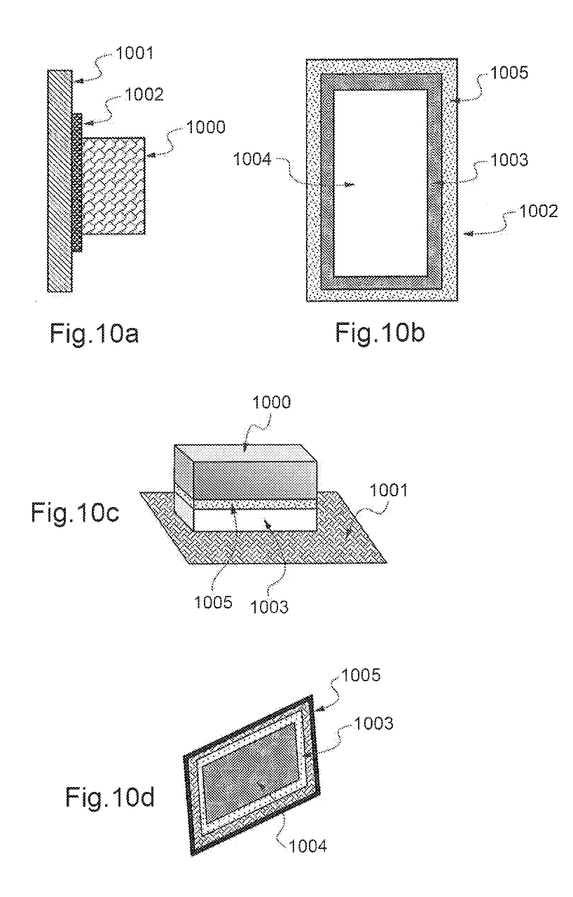

FIG. 10a is a general illustration of the fixing of a system according to embodiments. A conversion system 1000 is fixed to an internal wall 1001 of an aircraft fuselage by a fixing interface 1002.

In the mounting of FIG. 10a, the total thermal resistance is the sum of thermal resistance of the fuselage, of thermal resistance of the interface and of thermal resistance of the conversion system.

The interface can comprise a superposition of two layers of materials as illustrated by FIG. 10b. The interface can make it possible to fix a single system or any other number.

A first layer of material 1005 comprises a metal mounting plate on the aircraft (for example, AU4G type plate).

A second layer is positioned between the internal wall 1001 and the first layer 1005. This second layer is chosen to obtain a good trade-off in terms of fixing and of thermal conductivity (for example 3 W.m⁻¹.K⁻¹). It thus minimizes thermal resistance of the fixing interface and that of the assembly. The second layer has, for example, dimensions of 70×50 mm.

For example, the second layer itself comprises a two-material layer 1003 and 1004.

The sublayer of material 1004 has, for example, the following physical specifications: density of 2700-3700 kg/m³, a Young's modulus of 0.15-0.21 MPa, a thermal capacity of 500-1500 J.kg⁻¹.K⁻¹, a temperature range within the range 223-463 K, an electrical resistivity of 10⁸-10⁹ Ω.m and a dielectric breakdown voltage greater than 2800 V AC. The GAP PAD 3000S is an example of material that meets these specifications.

The sublayer of material 1003 is, for example, positioned around the sublayer of material 1004. The sublayer of material 1003 makes it possible to ensure the speed of mounting and reliability with respect to the aircraft environment. It is, for example, a double-sided adhesive tape. This tape has, for example, the same thickness as the sublayer of material 1004. This tape has, for example, a width of 5 mm.

FIG. 10c is a birds-eye view from the side of the mounted system. In this view, the sublayer of material 1004 does not appear because it is surrounded by the sublayer 1003.

The sublayer 1004 does, however, appear in the underside view of FIG. 10d.

According to these two views, it appears that the sublayer of material 1003 is positioned on the perimeter of the conversion system, thus leaving a surface inside the perimeter free to accommodate the sublayer 1004. Generally, the sublayer 1003 is positioned around the sublayer 1004. Since the two sublayers have the same thickness, when the system is mounted on the wall, the sublayer 1004 is well in thermal contact with the latter and the sublayer 1003 is also well in contact with the wall to allow the fixing.

The two sublayers of material can be incorporated in one and the same patch ready for use, in order to allow even easier mounting. This patch is, for example, adapted to the dimensions of the conversion systems used in the aircraft.

The patch can take the form of a roll that a user can unwind to cut an adhesive strip with thermally conductive material, to be glued onto a conversion system to then fix it to a wall.

The present disclosure has been described and illustrated in the present detailed description with reference to the attached figures. However, the present disclosure does not limit itself to the embodiments presented. Other variants, embodiments and combinations of features can be deduced and implemented by a person skilled in the art on reading the present description and the attached figures.

To satisfy specific needs, a person competent in the field of the disclosure herein will be able to apply modifications or adaptations.

A single processor or several other units can be used to implement the disclosure herein. The different features presented and/or claimed can be advantageously combined. Their presence in the description or in different dependent claims does not in fact exclude the possibility of combining them. The reference symbols should not be taken as limiting on the scope of the disclosure herein.

While at least one exemplary embodiment of the invention(s) is disclosed herein, it should be understood that modifications, substitutions and alternatives may be apparent to one of ordinary skill in the art and can be made without departing from the scope of this disclosure. This disclosure is intended to cover any adaptations or variations of the exemplary embodiment(s). In addition, in this disclosure, the terms “comprise” or “comprising” do not exclude other elements or steps, the terms “a” or “one” do not exclude a plural number, and the term “or” means either or both. Furthermore, characteristics or steps which have been described may also be used in combination with other characteristics or steps and in any order unless the disclosure or context suggests otherwise. This disclosure hereby incorporates by reference the complete disclosure of any patent or application from which it claims benefit or priority.

1. An energy conversion system, comprising:
a conversion unit for converting thermal energy into electrical energy, the unit comprising at least one thermal exchange surface for exchanging thermal energy with at least one external thermal source, and
a thermal inertia unit configured to cooperate with the conversion unit to slow down return of the conversion unit to a thermal balance upon the exchange of thermal energy.

2. The system of claim 1, in which thermal inertia unit comprises a phase-change material.

3. The system of claim 1, in which the conversion unit comprises a semiconductor-based circuit.

4. The system of claim 1, insulated by a protection jacket, the at least one thermal exchange surface remaining free for thermal exchange.

5. The system of claim 1, further comprising a storage unit for storing, at least partly, the converted electrical energy.

6. The system of claim 1, comprising at least one first thermal connection element in thermal contact with a first thermal exchange surface of the conversion unit, the first element being configured to guide a heat transfer between a first external thermal source and the first thermal exchange surface.

7. The system of claim 6, comprising at least one second thermal connection element in thermal contact with a second thermal exchange surface of the conversion unit, the second element being configured to guide a heat transfer between a second external thermal source and the second thermal exchange surface.

8. The system of claim 1, in which the at least one exchange surface is at least partly covered with an interface layer for thermal conduction with the at least one thermal source.

9. The system of claim 8, in which the interface layer comprises a sublayer of double-sided adhesive tape.

10. The system of claim 9, in which the double-sided adhesive tape is positioned around a sublayer of thermal conduction material.

11. The system of claim 10, in which the sublayers of double-sided adhesive tape and of thermal conduction material have one and the same thickness.

12. The system of claim 10, in which the sublayers of double-sided adhesive tape and of thermal conduction material are incorporated in one and the same independent interface element.

13. An aircraft comprising a system of claim 1.

14. The aircraft of claim 13, in which the at least one thermal source is chosen from the structural elements of the aircraft.

15. The aircraft of claim 13, in which the system supplies at least one sensor with electrical energy.

16. A method for supplying electrical power to an electrical device in an aircraft, comprising:
selection of at least one thermal source in the aircraft;
thermal contact of at least one exchange surface of a conversion unit of a system of claim 1 with the at least one selected thermal source; and
connection of the system to the electrical device.

17. The method of claim 16, in which the at least one thermal source is selected from the structural elements of the aircraft.

18. The method of claim 16, in which the at least one thermal source is chosen in such a way as to optimize a temperature difference within the conversion unit of the system.
